(19) United States
(12) Patent Application Publication
(10) Pub. No.: US 2013/0047418 A1
(43) Pub. Date: Feb. 28, 2013

(54) METHOD OF MANUFACTURING MULTILAYER PRINTED CIRCUIT BOARD

(71) Applicants: Yang Je Lee, Chungcheongbuk-do (KR); Gi Suk Kim, Gyeonggi-do (KR); Joong Hyuk Jung, Busan (KR); Dek Gin Yang, Chungbuk (KR)

(72) Inventors: Yang Je Lee, Chungcheongbuk-do (KR); Gi Suk Kim, Gyeonggi-do (KR); Joong Hyuk Jung, Busan (KR); Dek Gin Yang, Chungbuk (KR)

(73) Assignee: Samsung Electro-Mechanics, Suwon (KR)

(21) Appl. No.: 13/568,693

(22) Filed: Aug. 7, 2012

(30) Foreign Application Priority Data
Aug. 30, 2011 (KR) 10-2011-0087369

(51) Int. Cl. H05K 3/02

(52) U.S. Cl. 29/593; 29/846

(57) ABSTRACT

The present invention discloses a method of manufacturing a multilayer PCB including: a panel preparation step of preparing a working panel on which a plurality of PCB units having a plurality of inner layer circuit pattern portions are arrayed; a defective portion removing step of removing a defective inner layer circuit pattern portion among the plurality of inner layer circuit pattern portions; a good portion providing step of providing a good inner layer circuit pattern portion in a portion of the working panel, from which the defective inner layer circuit pattern portion is removed; and an outer layer forming step of forming an outer layer circuit pattern portion in the PCB unit. The present invention is capable of improving productivity and reducing manufacturing costs by preventing product loss due to disposal of the PCB unit having the defective inner layer circuit pattern portion.

### CROSS-REFERENCE TO RELATED APPLICATIONS

Claim and incorporate by reference domestic priority application and foreign priority application as follows:

CROSS REFERENCE TO RELATED APPLICATION

This application claims the benefit under 35 U.S.C. Section 119 of Korean Patent Application Serial No. 10-2011-0087369, entitled filed Aug. 30, 2011, which is hereby incorporated by reference in its entirety into this application.

### BACKGROUND OF THE INVENTION

1. Field of the Invention

The present invention relates to a method of manufacturing a multilayer printed circuit board, and more particularly, to a method of manufacturing a multilayer printed circuit board that is capable of reducing manufacturing costs required for disposal at the time of failure of an inner layer circuit pattern portion and improving productivity.

2. Description of the Related Art

In recent times, according to a trend of sets such as a hand-held phone (HHP) and a dye-sensitized solar cell (DSC), diverse attempts have been made to achieve reduction in thickness and manufacturing costs. Accordingly, there is an increasing need for a method with competitiveness of manufacturing costs while seeking reduction in thickness and increase in density of a printed circuit board (PCB) embedded in the HHP or the DSC.

Hereinafter, a typical method of manufacturing a multilayer PCB will be described in more detail with reference to FIGS. 1 and 2.

As shown in FIG. 1, first, an inner layer PCB sheet 1 on which a plurality of PCB units 11 having a plurality of inner layer circuit pattern portions 11a are arrayed is prepared, and as shown in FIG. 2, an outer layer PCB sheet 2 is manufactured by forming outer layer circuit pattern portions 11b in the inner layer circuit pattern portions 11a of the PCB unit 11. After that, a plurality of multilayer PCBs are manufactured by cutting the outer layer PCB sheet 2 into the PCB units 11.

However, a conventional method of manufacturing a multilayer PCB has the following problems.

That is, typically, in a process of manufacturing a multilayer PCB, the inner layer PCB sheet 1 is inspected before being manufactured into the outer layer PCB sheet 2. At this time, when at least one of the inner layer circuit pattern portions 11a is determined as defective, since the PCB unit having the inner layer circuit pattern portion determined as defective should be scrapped or the entire inner layer PCB sheet should be scrapped, there is a problem of loss of yield.

Further, even when the inspection is performed after manufacture of the outer layer PCB sheet 2 is completed, correction of open failure and so on of the outer layer circuit pattern portion 11b is possible, but when the inner layer circuit pattern portion 11a is defective, although the outer layer circuit pattern portion 11b is normal, the PCB unit including the defective inner layer circuit pattern portion 11a should be scrapped or the entire outer layer PCB sheet should be scrapped. So there is a problem of loss of yield.

Therefore, the conventional method of manufacturing a multilayer PCB has a problem of deterioration of productivity and workability. Accordingly, there is a problem of increase in manufacturing costs.

### SUMMARY OF THE INVENTION

The present invention has been invented in order to overcome the above-described problems and it is, therefore, an object of the present invention to provide a method of manufacturing a multilayer PCB that is capable of improving productivity and reducing manufacturing costs by preventing product loss due to disposal of a PCB unit having a defective inner layer circuit pattern portion at the time of failure of the existing inner layer circuit pattern portion.

It is another object of the present invention to provide a method of manufacturing a multilayer PCB that is capable of further improving workability and productivity and reducing manufacturing costs by performing post-processes such as formation of an outer layer circuit pattern portion in a state in which a plurality of PCB units having only good inner layer circuit pattern portions are arrayed on a working panel.

In accordance with one aspect of the present invention to achieve the object, there is provided a method of manufacturing a multilayer PCB including: a panel preparation step of preparing a working panel on which a plurality of PCB units having a plurality of inner layer circuit pattern portions are arrayed; a defective portion removing step of removing a defective inner layer circuit pattern portion among the plurality of inner layer circuit pattern portions; a good portion providing step of providing a good inner layer circuit pattern portion in a portion of the working panel, from which the defective inner layer circuit pattern portion is removed; and an outer layer forming step of forming an outer layer circuit pattern portion in the PCB unit.

The method of manufacturing a multilayer PCB may include, after the panel preparation step, an inspection step of inspecting the plurality of inner layer circuit pattern portions.

Here, the inspection step may be performed by using at least one of an auto optical inspection (AOI) and an electrical continuity test.

Meanwhile, the defective portion removing step may be performed by one of laser processing, CNC routing, and mold punching.

And the good inner layer circuit pattern portion may be provided by being removed from another working panel with the same shape as the working panel.

Further, the good inner layer circuit pattern portion may be provided in the portion of the working panel, from which the defective inner layer circuit pattern portion is removed, by one of a coupling method or an adhesion method using an adhesive member.

At this time, the coupling method may be a method of press-fitting a groove and a projection, and the adhesive member applied to the adhesion method may include a carrier tape or an adhesive.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a configuration diagram roughly showing a working panel on which a plurality of PCB units having inner layer circuit pattern portions are arrayed in accordance with the prior art;

FIG. 2 is a configuration diagram roughly showing that an outer layer circuit pattern portion is formed in the inner layer circuit pattern portion of FIG. 1;

FIG. 3 is a block diagram roughly showing an embodiment of a method of manufacturing a multilayer PCB in accordance with the present invention;

FIGS. 4a to 4e are configuration diagrams sequentially showing an embodiment of the method of manufacturing a multilayer PCB in accordance with the present invention, wherein FIG. 4a is a configuration diagram roughly showing that a defective inner layer circuit pattern portion is indicated as a result of inspection of the working panel after a panel preparation step, FIG. 4b is a configuration diagram roughly showing a state in which the defective inner layer circuit pattern portion of FIG. 4a is removed, FIG. 4c is a configuration diagram roughly showing that a good inner layer circuit pattern portion is taken out from a separate working panel, FIG. 4d is a configuration diagram roughly showing a state in which the good inner layer circuit pattern portion taken out in FIG. 4c is provided in a portion of the working panel, from which the defective inner layer circuit pattern portion is removed, and FIG. 4e is a configuration diagram roughly showing the working panel on which the plurality of PCB units having only the good inner layer circuit pattern portions are arrayed, after the processes of FIGS. 4a to 4d; and

FIGS. 5a to 5r are cross-sectional views roughly showing an embodiment of the method of manufacturing a multilayer PCB in accordance with the present invention by limiting the PCB unit.

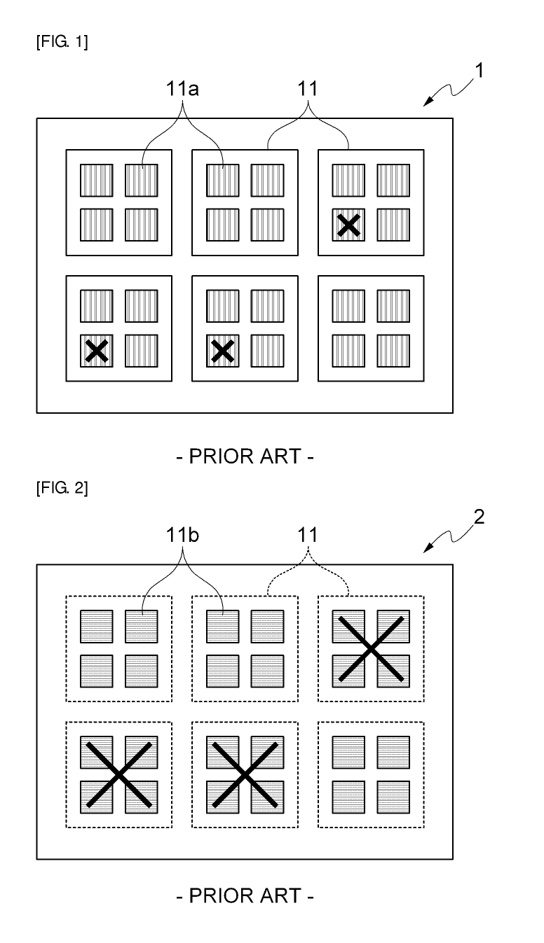

### DETAILED DESCRIPTION OF THE PREFERABLE EMBODIMENTS

Hereinafter, preferable embodiments of the present invention to achieve the above-described objects will be described with reference to the accompanying drawings. In this description, the same elements are represented by the same names and the same reference numerals, and additional description which is repeated or limits interpretation of the meaning of the invention may be omitted.

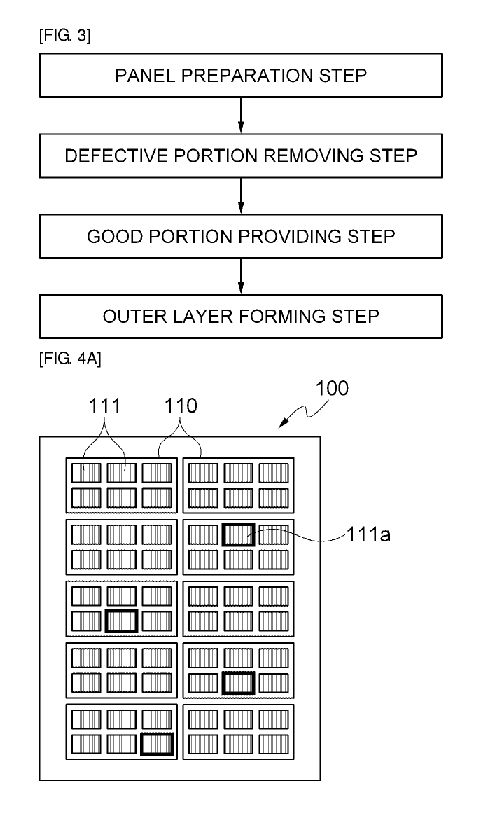

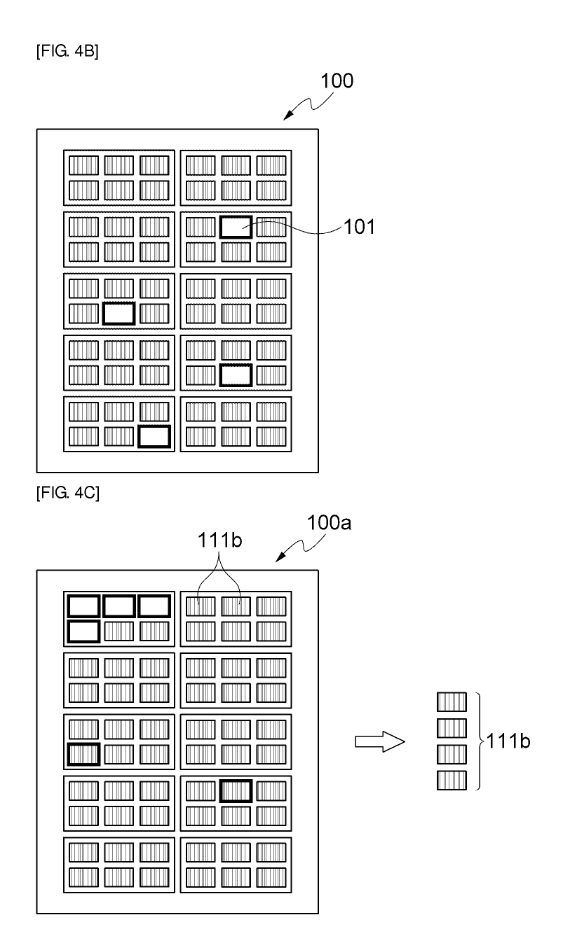

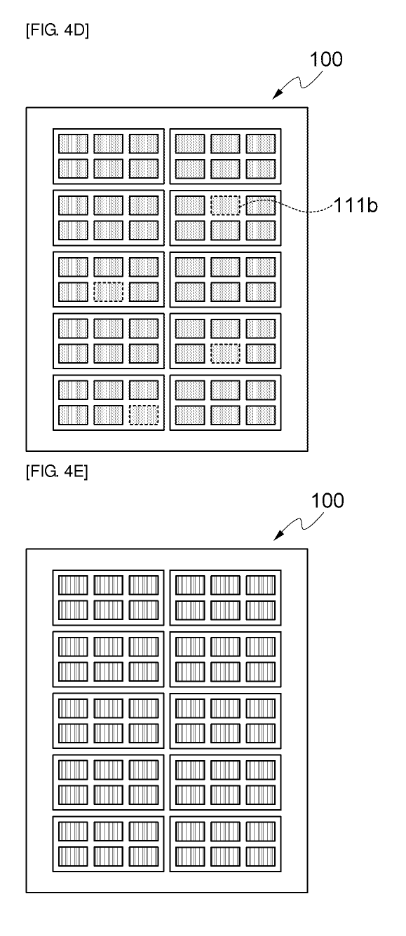

First, an embodiment of a method of manufacturing a multilayer PCB in accordance with the present invention will be described in detail with reference to the accompanying FIGS. 3 to 4e.

FIG. 3 is a block diagram roughly showing an embodiment of a method of manufacturing a multilayer PCB in accordance with the present invention, and FIGS. 4a to 4e are configuration diagrams sequentially showing an embodiment of the method of manufacturing a multilayer PCB in accordance with the present invention, wherein FIG. 4a is a configuration diagram roughly showing that a defective inner layer circuit pattern portion is indicated as a result of inspection of the working panel after a panel preparation step, FIG. 4b is a configuration diagram roughly showing a state in which the defective inner layer circuit pattern portion of FIG. 4a is removed, FIG. 4c is a configuration diagram roughly showing that a good inner layer circuit pattern portion is taken out from a separate working panel, FIG. 4d is a configuration diagram roughly showing a state in which the good inner layer circuit pattern portion taken out in FIG. 4c is provided in a portion of the working panel, from which the defective inner layer circuit pattern portion is removed, and FIG. 4e is a configuration diagram roughly showing the working panel on which the plurality of PCB units having only the good inner layer circuit pattern portions are arrayed, after the processes of FIGS. 4a to 4d.

Referring to FIG. 3, an embodiment of a method of manufacturing a multilayer PCB in accordance with the present invention includes a panel preparation step, a defective portion removing step, a good portion providing step, and an outer layer forming step.

More specifically, as shown in FIG. 4a, first, a working panel 100 on which a plurality of PCB units 110 having a plurality of inner layer circuit pattern portions 111 are arrayed is prepared.

Here, the method of manufacturing a multilayer PCB in accordance with this embodiment may perform an inspection step of inspecting the plurality of inner layer circuit pattern portions 111.

At this time, the inspection step may be performed by using one of an auto optical inspection (AOI) or an electrical continuity test.

That is, it is possible to inspect whether circuit patterns of the plurality of inner layer circuit pattern portions 111 are accurately formed according to design data through the AOI, and it is possible to inspect whether electrical connection of the plurality of inner layer circuit pattern portions 111 is well configured through the electrical continuity test. Through this inspection process, it is possible to detect a defective inner layer circuit pattern portion 111a.

Next, as shown in FIG. 4b, it is possible to remove the defective inner layer circuit pattern portion 111a among the plurality of inner layer circuit pattern portions 111.

At this time, the removal of the defective inner layer circuit pattern portion 111a may be performed by one of laser processing, CNC routing, and mold punching.

In addition, as shown in FIG. 4c, apart from the removal of the defective inner layer circuit pattern unit 111a, a good inner layer circuit pattern portion 111b is taken out from another working panel 100a.

At this time, like the above-described method of removing the defective inner layer circuit pattern portion 111a, the take-out of the good inner layer circuit pattern unit 111b may be performed by one of laser processing, CNC routing, and mold punching.

Next, as in FIG. 4d, the good inner layer circuit pattern portion 111b taken out in the process of FIG. 4c is provided in a portion 101 of the working panel 100, from which the defective inner layer circuit pattern portion 111a is removed, as a substitute.

At this time, the good inner layer circuit pattern portion 111b may be provided in the portion 101 of the working panel 100, from which the defective inner layer circuit pattern portion 111a is removed, by one of a coupling method and an adhesion method using an adhesive member.

At this time, the coupling method may be a method of press-fitting a groove and a projection, and the adhesive member applied to the adhesion method may include a carrier tape. The carrier tape is a film type adhesive tape of which both surfaces are adhesive surfaces, and the other adhesive surface is attached to the portion 101 of the working panel 100, from which the defective inner layer circuit pattern portion 111a is removed, in a state in which one adhesive surface is attached to the good inner layer circuit pattern portion 111b so that the good inner layer circuit pattern portion 111b can be provided as a substitute.

Further, the adhesive member may include an adhesive. That is, the good inner layer circuit pattern portion 111b may be fixed to the portion 101 of the working panel 100, from which the defective inner layer circuit pattern portion 111a is removed or the portion 101 of the working panel 100, from which the defective inner layer circuit pattern portion 111a is removed after the adhesive is applied on the good inner layer circuit pattern portion 111b.

Then, as in FIG. 4e, it is possible to obtain the working panel on which the PCB units having only the good inner layer circuit pattern portions are arrayed.

After that, manufacture of a plurality of single multilayer PCBs is completed by forming outer layer circuit pattern portions in the respective good inner layer circuit pattern portions of the plurality of PCB units, performing post-processes such as a surface treatment process, and dicing the working panel into the plurality of PCB units.

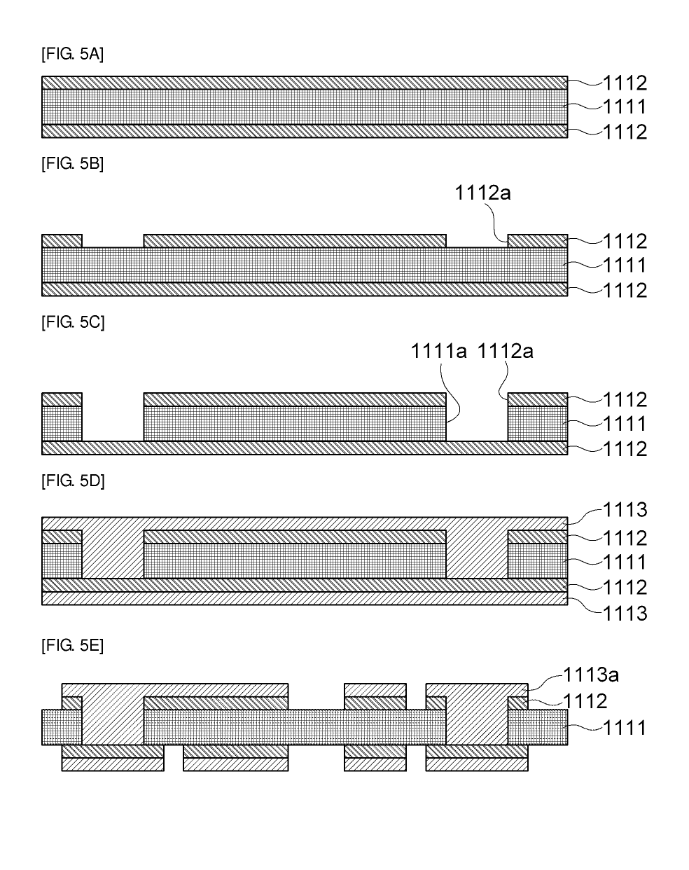

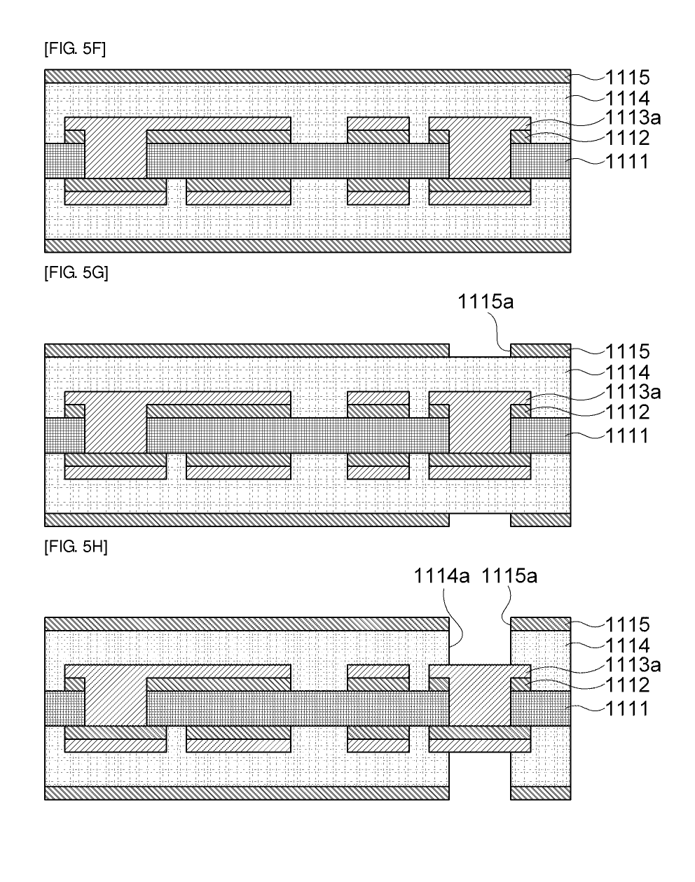

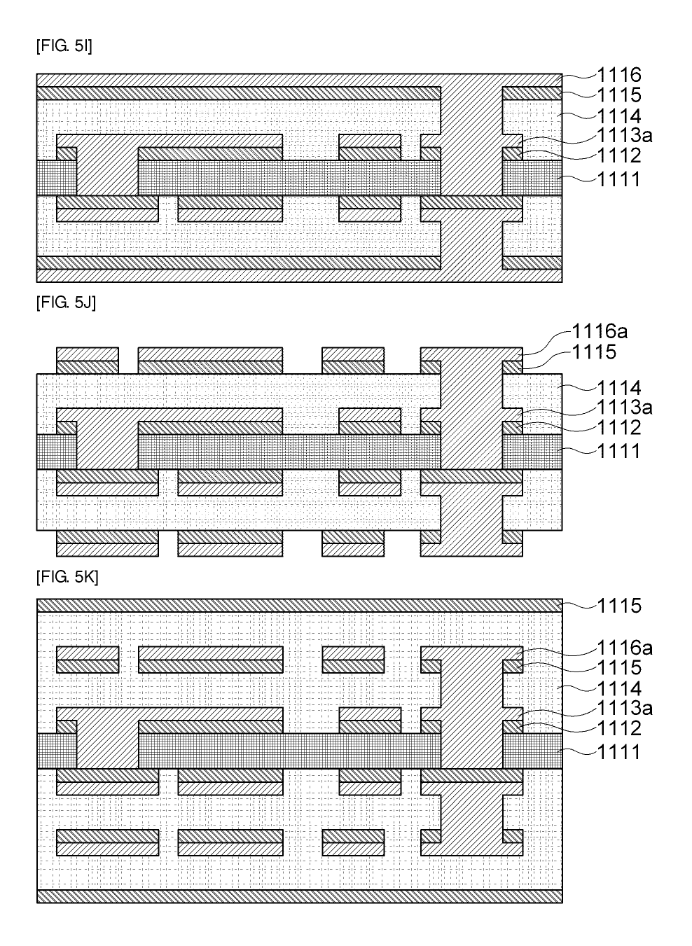

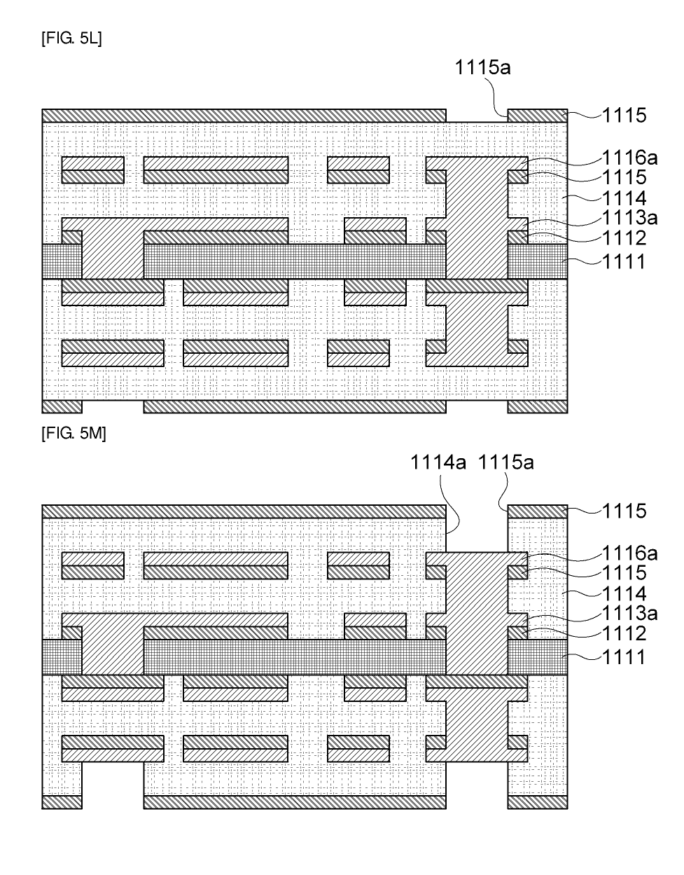

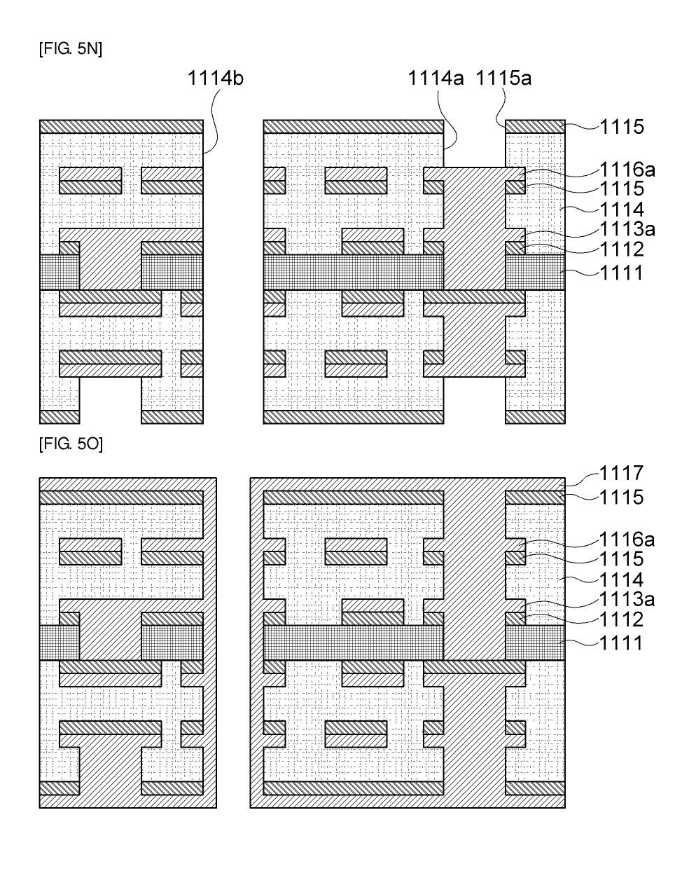

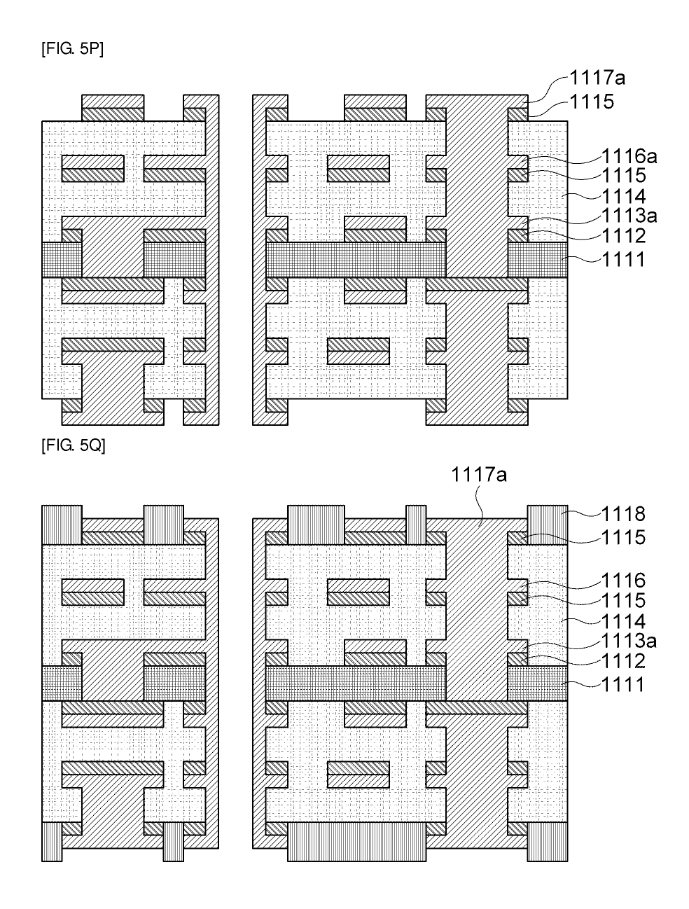

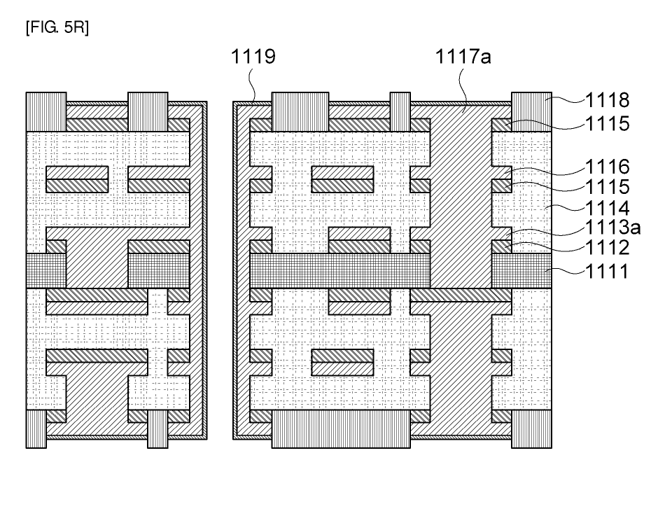

Meanwhile, FIGS. 5a to 5r are cross-sectional views roughly showing an embodiment of the method of manufacturing a multilayer PCB in accordance with the present invention by limiting the PCB unit. A structure and a manufacturing method of a multilayer PCB in accordance with this embodiment will be described in detail with reference to FIGS. 5a to 5r.

First, as shown in FIG. 5a, a copper clad laminate (CCL) which is formed by laminating copper foils 1112 on both surfaces of an interlayer insulator 1111 is prepared.

And as shown in FIG. 5b, a via window 1112a is formed in the copper foil 1112 by laser.

Next, as shown in FIG. 5c, a via 1111a is formed in the interlayer insulator 1111 by laser.

And as shown in FIG. 5d, a plating layer 1113 is formed by performing plating on the via 1111a and the copper foil 1112.

After that, as shown in FIG. 5e, a first inner layer circuit pattern 1113a including the patterned copper foil is formed by performing a patterning process on the plating layer 1113 and the copper foil 1112.

Next, as shown in FIG. 5f, an interlayer insulating adhesive 1114 and a copper foil 1115 are laminated on the first inner layer circuit pattern 1113a.

And as shown in FIG. 5g, a via window 1115a is formed in the copper foil 1115 by laser.

After that, as shown in FIG. 5h, a via 1114a is formed in the interlayer insulating adhesive 1114 by laser.

And as shown in FIG. 5i, a plating layer 111 6 is formed by performing plating on the via 1114a and the copper foil 1115.

After that, as shown in FIG. 5j, a second inner layer circuit pattern 1116a including the patterned copper foil is formed by performing a patterning process on the plating layer 1116 and the copper foil 1115.

Meanwhile, although this embodiment discloses that the multilayer PCB consists of six layers as a reference, the number of layers of the multilayer PCB is not limited thereto and this embodiment can be applied to all products with more than four layers. Here, when the six layers are set as a reference in this embodiment, as described above, since the processes of forming the first inner layer circuit pattern 1113a and the second inner layer circuit pattern 1116a are mutually repeated laminating processes and a process of forming an outer layer circuit pattern is a final circuit pattern forming process after forming the second inner layer circuit pattern 1116a, it may be possible to detect a defective circuit pattern portion by performing one of the above-described AOI and electrical continuity test after forming the first inner layer circuit pattern 1113a, but it is preferable to perform a defect inspection after forming the second inner layer circuit pattern 1116a, that is, before the final step of forming the outer layer circuit pattern.

After forming the second inner layer circuit pattern 1116a as above, as described above, the defect inspection of the inner layer circuit pattern portion is performed and a defective inner layer circuit pattern portion is removed and substituted with a good inner layer circuit pattern portion by an inner layer piece bonding process.

After that, post-processes performed in a state in which the plurality of PCB units consisting of only the good inner layer circuit pattern portions are arrayed on the working panel are as follows.

That is, as shown in FIG. 5k, an interlayer insulating adhesive 1114 and a copper foil 1115 are laminated on the second inner layer circuit pattern 1116a again.

And as shown in FIG. 5l, a via window 1115a is formed in the copper foil 1115 by laser.

After that, as shown in FIG. 5m, a via 1114a is formed in the interlayer insulating adhesive 1114 by laser.

At this time, as shown in FIG. 5n, a CNC hole 1114b may be further formed according to products.

And as shown in FIG. 5o, a plating layer 1117 is formed by performing plating on the via 1114a, the CNC hole 1114b, and the copper foil 1115.

After that, as shown in FIG. 5p, an outer layer circuit pattern 1117a including the patterned copper foil is formed by performing a patterning process on the plating layer 1117 and the copper foil 1115.

Next, as shown in FIG. 5q, a PSR process, that is, a process of applying ink is performed to prevent solder from being attached to an unnecessary portion due to attachment of solder when mounting chips such as electronic components between the outer layer circuit patterns 1117a and to protect an outer layer circuit, that is, a surface circuit from external environment. This can be completed by sequentially performing exposure, development, and drying processes after applying the PSR ink.

Finally, as shown in FIG. 5r, a surface treatment process is performed for functions such as prevention of oxidation of a surface of the outer layer circuit pattern 1117a.

That is, a process of forming an electroless plating layer 1119 on the outer layer circuit pattern 1117a may be performed.

As described above, according to a method of manufacturing a multilayer PCB in accordance with the present invention, it is possible to improve productivity and reduce manufacturing costs by preventing product loss due to disposal of a PCB unit having a defective inner layer circuit pattern portion at the time of failure of the existing inner layer circuit pattern portion.

Further, according to a method of manufacturing a multilayer PCB in accordance with the present invention, it is possible to further improve productivity and reduce manufacturing costs by performing post-processes such as formation of an outer layer circuit pattern portion in a state in which a plurality of PCB units having only good inner layer circuit pattern portions are arrayed on a working panel.

The above-described preferable embodiments of the present invention are provided as examples, and it will be appreciated by those skilled in the art that diverse substitutions, modifications and variations may be made in these embodiments without departing from the technical spirit of the present invention. However, it is to be understood that these substitutions, modifications, and variations are included in the appended claims.

1. A method of manufacturing a multilayer PCB comprising:
preparing a working panel on which a plurality of PCB units having a plurality of inner layer circuit pattern portions are arrayed;
removing a defective inner layer circuit pattern portion among the plurality of inner layer circuit pattern portions;
providing a good inner layer circuit pattern portion in a portion of the working panel, from which the defective inner layer circuit pattern portion is removed; and
forming an outer layer circuit pattern portion in the PCB unit.

2. The method of manufacturing a multilayer PCB according to claim 1, further comprising, after the preparing a working panel, inspecting the plurality of inner layer circuit pattern portions.

3. The method of manufacturing a multilayer PCB according to claim 2, wherein the inspecting is performed by using at least one of an auto optical inspection (AOI) and an electrical continuity test.

4. The method of manufacturing a multilayer PCB according to claim 1, wherein the removing a defective pattern portion is performed by one of laser processing, CNC routing, and mold punching.

5. The method of manufacturing a multilayer PCB according to claim 1, wherein the good inner layer circuit pattern portion is provided by being removed from another working panel with the same shape as the working panel.

6. The method of manufacturing a multilayer PCB according to claim 1, wherein the good inner layer circuit pattern portion is provided by one of a coupling method and an adhesion method using an adhesive member.

7. The method of manufacturing a multilayer PCB according to claim 6, wherein the coupling method is a method of press-fitting a groove and a projection.

8. The method of manufacturing a multilayer PCB according to claim 6, wherein the adhesive member applied to the adhesion method comprises a carrier tape.

9. The method of manufacturing a multilayer PCB according to claim 6, wherein the adhesive member applied to the adhesion method comprises an adhesive.
